(19) United States
(12) Patent Application Publication
(10) Pub. No.: US 2015/0302918 A1
(43) Pub. Date: Oct. 22, 2015

(54) WORD LINE DECODERS FOR DUAL RAIL STATIC RANDOM ACCESS MEMORIES

(71) Applicant: LSI Corporation, San Jose, CA (US)

(72) Inventors: Rajiv Kumar Roy, Bangalore (IN); Rasoju Veerabadra Chary, Bangalore (IN); Dharmendra Kumar Rai, Bangalore (IN); Rahul Sahu, Bangalore (IN)

(73) Assignee: LSI CORPORATION, San Jose, CA (US)

(21) Appl. No.: 14/258,236

(22) Filed: Apr. 22, 2014

(51) Int. Cl. G11C 11/418

(52) U.S. Cl. CPC G11C 11/418

(57) ABSTRACT

Word line decoders for dual rail SRAM devices are disclosed for high performance sub-micron SRAM designs. One embodiment is an SRAM device that includes a memory cell array and a word line traversing the memory cell array for selecting memory cells of the memory cell array. A row decode-driver coupled to the word line toggles the word line between logic levels of a memory cell supply based on select signals that toggle between logic levels of a peripheral supply. The row decoder-driver toggles the word line without utilizing level shifters along the word line access path.

### FIELD OF THE INVENTION

The invention generally relates to field of word line circuits for memory devices.

### BACKGROUND

Sub-micron Integrated Circuit (IC) designs often utilize a number of different power supplies to reduce power consumption and to improve performance. For example, in sub-micron Static Random Access Memories (SRAM) devices, higher voltage supplies may be utilized for the memory cells to improve the reliability and performance, while peripheral circuits may utilize lower voltage supplies to reduce the power consumption. Level shifters are used to translate the logic level signals of the word line decoder/drivers to the logic level signals of the memory cells for proper functionality. However, level shifters in the word line signaling path may introduce delays in generating word line signals, which degrades the performance of the SRAM device.

### SUMMARY

Word line decoder-drivers for dual rail SRAM devices are disclosed for high performance sub-micron SRAM designs. One embodiment is an SRAM device that includes a memory cell array and a word line traversing the memory cell array. The word line is utilized for selecting memory cells of the memory cell array. The SRAM device further includes a level shift circuit that is configured to receive a first select signal that toggles between logic levels defined by a peripheral supply, and to translate the first select signal to logic levels defined by a memory cell supply to generate a level-shifted select signal. The SRAM device further includes a row decode-driver that is configured to toggle the word line. The row decode-driver includes an inverting driver coupled to the word line that is configured to toggle the word line between the logic levels defined by the memory cell supply based on an internal signal. The row decode-driver further includes a first pull-up circuit that is configured to couple the internal signal to the memory cell supply based on the level-shifted signal and the first select signal. The row decode-driver further includes a second pull-up circuit that is configured to couple the internal signal to the memory cell supply based on a logic level of the word line and a second select signal. The second select signal toggles between the logic levels defined by the peripheral supply. The row decoder-driver further includes a pull-down circuit that is configured to couple the internal signal to ground based on the first select signal and the second select signal.

The various embodiments disclosed herein may be implemented in a variety of ways as a matter of design choice. For example, some embodiments herein are implemented in hardware whereas other embodiments may include processes that are operable to construct and/or operate the hardware. Other exemplary embodiments are described below.

### BRIEF DESCRIPTION OF THE FIGURES

Some embodiments of the present invention are now described, by way of example only, and with reference to the accompanying drawings. The same reference number represents the same element or the same type of element on all drawings.

FIG. 1 is a block diagram of an exemplary SRAM architecture.

FIG. 2 is a block diagram of a word line row decode-driver in an exemplary embodiment.

FIG. 3 is a schematic diagram of the word line row decode-driver of FIG. 2 in an exemplary embodiment.

FIG. 4 is a schematic diagram illustrating additional details for the word line row decode-driver of FIG. 3 in an exemplary embodiment.

### DETAILED DESCRIPTION OF THE FIGURES

The figures and the following description illustrate specific exemplary embodiments of the invention. It will thus be appreciated that those skilled in the art will be able to devise various arrangements that, although not explicitly described or shown herein, embody the principles of the invention and are included within the scope of the invention. Furthermore, any examples described herein are intended to aid in understanding the principles of the invention and are to be construed as being without limitation to such specifically recited examples and conditions. As a result, the invention is not limited to the specific embodiments or examples described below.

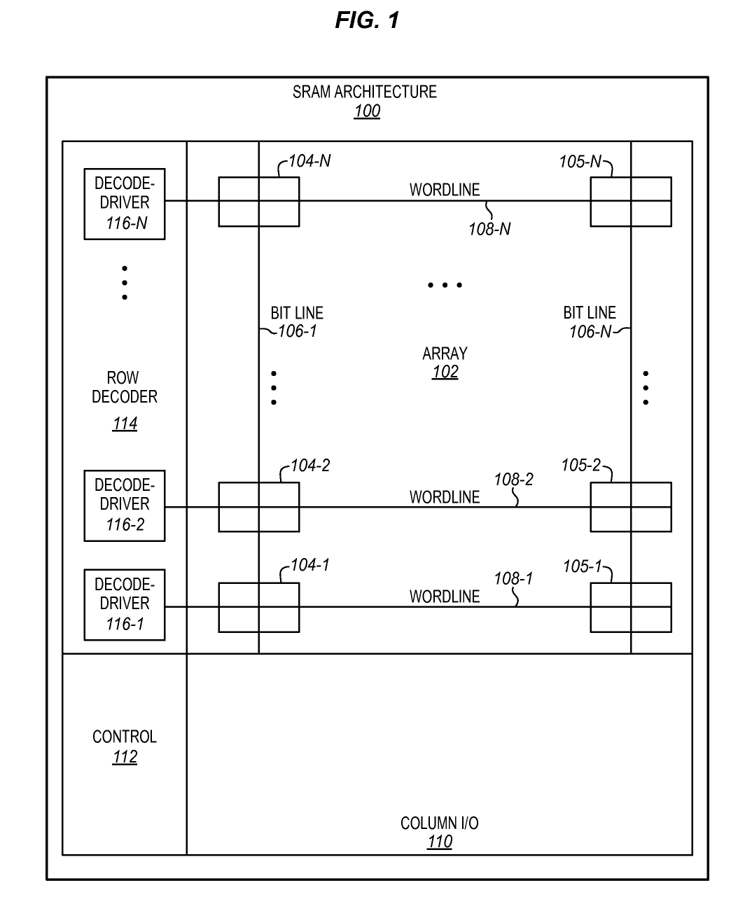

FIG. 1 is a block diagram of an exemplary SRAM architecture 100. Architecture 100 is a simplified block diagram view that will be used to discuss the inventive aspects of the SRAM devices disclosed herein. But, architecture 100 is not intended to limit the implementation to any particular embodiment. Those skilled in the art will understand that additional components not shown or described in FIG. 1, such as drivers, latches, decoders, sense amps, etc. may be used to implement architecture 100 in various configurations as a matter of design choice.

Architecture 100 in this embodiment includes an array 102 of memory cells 104-105. Memory cells 104-105 are disposed in array 102 at the intersections of column bit lines 106 and row word lines 108. For instance, memory cell 104-1 is disposed in array 102 where bit line 106-1 intersects word line 108-1. To access memory cell 104-1, word line 108-1 is asserted utilizing a decode-driver 116-1 of a row decoder circuit 114, and bit data stored at memory cell 104-1 is read out, or written by, bit line 106-1 utilizing circuits within column I/O 110. Bit lines 106 may be complimentary bit lines or single ended bit lines as a matter of design choice. A control block 112 receives clock and address inputs and generates various control signals for architecture 100.

In this embodiment, memory cells 104-105 operate at a higher voltage than the circuits in row decoder 114. Utilizing different voltage supplies improves the performance of memory cells 104-105, while reducing the power consumption of circuits that operate within row decoder 114. In this embodiment, row decoder 114 utilizes one or more select signals for asserting word lines 108. The select signals may be pre-decode signals generated from portions of a memory cell address, which are then used to select a particular word line 108. In other embodiments, one or more of the select signals may be “bank select” signals depending on the organization of memory cells 104-105 in array 102.

In this embodiment, the select signals toggle between logic levels defined by a peripheral supply of row decoder 114, while word lines 108 toggle between logic levels defined by the memory cell supply of memory cells 104-105. For example, the peripheral supply may be at 0.72 volts while the memory cell supply may be at 0.92 volts. Thus, part of the activity of decode drivers 116 is to ensure that signaling of word lines 108 transition between logical states of the memory cell supply based on select signals that transition between logical states of the peripheral supply.

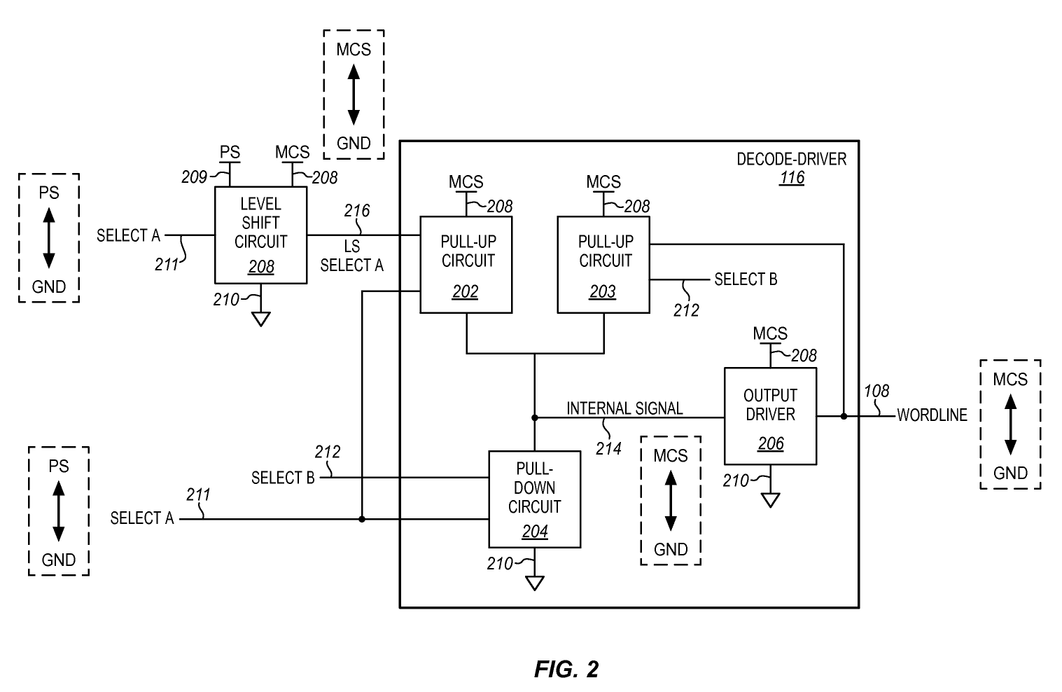

In this embodiment, decode-driver 116 does not include level shifters in an access path for word lines 108, although decode-driver 116 is capable of generating word lines 108 at the higher voltage of the memory cell supply based on select signals that operate at the lower voltage of the peripheral supply. This reduces the delay along the access path used to generate word lines 108, which improves the read/write performance of architecture 100. The specifics of how decode-driver 116 may operate in such a dual rail environment will become more readily apparent in discussing FIGS. 2-4.

FIG. 2 is a block diagram of decode-driver 116 in an exemplary embodiment. In this embodiment, decode-driver 116 includes pull-up circuits 202-203, a pull-down circuit 204, and an output driver 206. Decode-driver 116 receives select signals 211-212 and sets the logic level of word line 108 based on select signals 211-212. For instance, decode-driver 116 may set word line 108 to a logical one in response to select signals 211-212 at a logical one, and set word line 108 to a logical zero in response to either of select signals 211-212 at a logical zero.

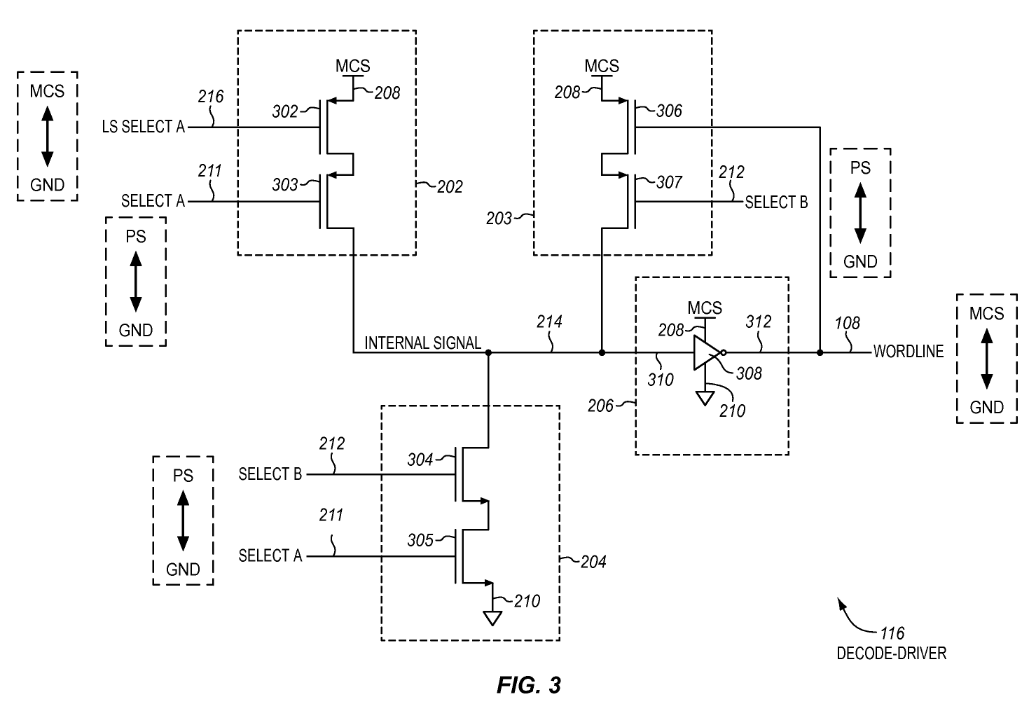

Select signals 211-212 transition between logic levels defined by peripheral supply 209, while word line 108 transitions between logic levels defined by memory cell supply 208. For instance, when select signal 211 is a logical one, the voltage for select signal 211 may be approximately equal to the voltage at peripheral supply 209. When word line 108 is a logical one, the voltage for word line 108 may be approximately equal to the voltage at memory cell supply 208. A level shifter circuit 208 is illustrated in FIG. 2, which generates a level-shifted select signal 216 by translating select signal 211 from the logic levels of peripheral supply 209 to the logic levels of memory cell supply 208. But, level shift circuit 208 is not in an access path for generating word line 108, and therefore any signaling delay that may occur across level shift circuit 208 does not impact the generation of word line 108. This will be discussed later with respect to FIG. 3.

Level shift circuit 208 may be included within row decoder 114 and/or control 112 as a matter of design choice. Further, level shift circuit 208 may be shared by multiple instances of decode-driver 116 in row decoder 114. For instance, when pre-decode or select signals are shared by multiple instances of decode-driver 116, each instance of decode-driver 116 may share a common level shifter. Since each instance of decode-driver 116 does not utilize its own level shifter, this reduces the die size impact of implementing decode-driver 116 in architecture 100.

In FIG. 2, pull-up circuit 202 of decode-driver 116 is coupled to memory cell supply 208 and an internal signal 214, and toggles internal signal 214 that is used by output driver 206 to generate word line 108. In particular, pull-up circuit 202 includes any component or device that is able to couple internal signal 214 to memory cell supply 208 based on select signal 211 and level-shifted select signal 216. Pull-up circuit 203 of decode-driver 116 is coupled to memory cell supply 208, and also toggles internal signal 214 that is used by output driver 206 to generate word line 108. More specifically, pull-up circuit 203 includes any component or device that is able to couple internal signal 214 to memory cell supply 208 based on select signal 212 and the logic level of word line 108.

Pull-down circuit 204 is coupled to a ground 210 and internal signal 214, and toggles internal signal 214 that is used by output driver 206 to generate word line 108. In particular, pull-down circuit 204 includes any component or device that is able to couple internal signal 214 to ground 210 based on select signals 211-212.

As discussed previously, output driver 206 generates word line 108 based on internal signal 214. Output driver 206 is coupled to memory cell supply 208 and ground 210, and may be an inverting driver in some embodiments. When output driver 206 is an inverting driver, the logic levels on word line 108 are the compliment of internal signal 214. Thus, when internal signal 214 is approximately at a voltage of memory cell supply 208, word line 108 is approximately at a voltage of ground 210. In like manner, when internal signal 214 is approximately at the voltage of ground 210, word line 108 is at approximately the voltage of memory cell supply 208. In this embodiment, memory cell supply 208 and peripheral supply 209 share ground 210, although in other embodiments, memory cell supply 208 and peripheral supply 209 may utilize separate ground references as a matter of design choice.

FIG. 3 is a schematic diagram of decode-driver 116 of FIG. 2 in an exemplary embodiment. In this embodiment, a number of Field-Effect Transistors (FETs) 302-307 and an inverter 308 are illustrated in a particular configuration for implementing the functionality previously described for decode-driver 116 of FIG. 2. FETs 302-307 may include any type of field-effect transistor as a matter of design choice. One example of a FET is a Metal Oxide Semiconductor Field Effect Transistor (MOSFET). Although FIG. 3 illustrates one configuration of a number of FETs and an inverter, one skilled in the art will understand other configurations may be implemented as a matter of design choice. Thus, it is not intended that decode-driver 116 be limited to only the configuration and types of components illustrated in FIG. 3. A discussion of the circuits illustrated in FIG. 3 will begin with select signals 211-212 set to a logical zero. When both select signals 211-212 are at a logical zero, the voltages of select signals 211-212 are approximately the voltage of ground 210.

Pull-down circuit 204 of decode-driver 116 includes a series stack of N-channel FETs 304-305 between internal signal 214 and ground 210. FET 304 has a drain coupled to internal signal 214, a source coupled to the drain of FET 305, and a gate coupled to select signal 212. FET 305 is source coupled to ground 210 with a gate terminal coupled to select signal 211. The series stack of FETs 304-305 are off, due to select signals 211-212 at approximately the voltage of ground 210 for a logical zero.

Pull-up circuit 202 of decode-driver 116 includes a series stack of P-channel FETs 302-303 between memory cell supply 208 and internal signal 214. With select signal 211 at a logical zero, level-shifted select signal 216 is also at a logical zero, which is approximately the voltage of ground 210. FET 302 is source coupled to memory cell supply 208 with a gate coupled to level-shifted select signal 216. FET 303 has a source coupled to the drain of FET 302, a gate coupled to select signal 211, and a drain coupled to internal signal 214. When select signal 211 and level-shifted select signal 216 are a logical low at approximately the voltage of ground 210, the series stack of FETs 302-303 are on. This charges internal signal 214 to the voltage of memory cell supply 208, which is a logical one.

Inverter 308 of output circuit 206 in this embodiment has an input 310 coupled to internal signal 214 and an output 312 coupled to word line 108. Inverter 308 is coupled to memory cell supply 208 and ground 210, and functions to invert the logical state of internal signal 214. When internal signal 214 is charged to the voltage of memory cell supply 208, inverter 308 sets word line 108 a logical zero at approximately the voltage of ground 210.

Pull-up circuit 203 of decode-driver 116 includes a series stack of P-channel FETs 306-307 between memory cell supply 208 and internal signal 214. FET 306 is source coupled to memory cell supply 208 and has a gate coupled to word line 108. FET 307 has a source coupled to a drain of FET 306, a gate coupled to select signal 212, and a drain coupled to internal signal 214. With both word line 108 and select signal 212 at a logical zero, FETs 306-307 are on. This also charges internal signal 214 to the voltage of memory cell supply 208. Thus, with both select signals 211-212 at a logical zero, both pull-up circuits 202-203 charge internal signal 214 to the voltage of memory cell supply 208, which holds word line 108 at a logical zero. Pull-down circuit 204 is in a high impedance state, and there is no leakage path from memory cell supply 208 to ground 210.

During operation, both select signals 211-212 are set to a logical one in order to set word line 108 to a logical one. With both select signals 211-212 toggling to a logical one, the voltage of select signals 211-212 are approximately the voltage of peripheral supply 209. FETs 304-305 of pull-down circuit 204 turn on, which couples internal signal 214 to ground 210. With select signal 211 at approximately the voltage of peripheral supply 209, FET 303 of pull-up circuit 202 may not fully turn off. There may be a delay through level shift circuit 208 (see FIG. 2) when generating level-shifted select signal 216 from select signal 211, so FET 302 may remain on for the delay time. This may cause a transient current to flow from memory cell supply 208 through FETs 302-305 to ground 210 as internal signal 214 is discharged by pull-down circuit 204. A similar transient case is present in pull-up circuit 203. With select signal 212 at approximately the voltage of peripheral supply 209, FET 307 of pull-up circuit 203 may not fully turn off. Word line 108 is at a logical low at this point and therefore FET 306 remains on. This may cause a transient current to flow from memory cell supply 208 through FETs 306-307 to ground 210 as internal signal 214 is discharged by pull-down circuit 204. However, FET 303 and FET 307 are only partially conducting, so internal signal 214 will discharge rapidly towards the voltage of ground 210.

When internal signal 214 discharges below the logic zero threshold voltage for inverter 308, inverter 308 sets word line 108 to a logical one at approximately the voltage of memory cell supply 208. This turns off FET 306 in pull-up circuit 203, which eliminates the transient current that may be flowing through pull-up circuit 203 to ground 210. Thus, pull-up circuit 203 is in a high impedance state and no leakage current flows from memory cell supply 208 through FETs 306-307 to ground 210.

After a small signaling delay across level shift circuit 208, level-shifted select signal 216 is set to a logical one at approximately the voltage of memory cell supply 208. This turns off FET 302 in pull-up circuit 202, which eliminates the transient current that may be flowing through pull-up circuit 202 to ground 210. Thus, pull-up circuit 202 is in a high impedance state and no leakage current flows from memory cell supply 208 through FETs 302-303 to ground 210.

With word line 108 set to a logical one, memory cells 104-105 coupled to word line 108 may be active for reading and/or writing utilizing bit line 106. If select signal 211 toggles to a logical zero, then word line 108 toggles to a logical zero. For instance, with select signal 212 at a logical one and select signal 211 toggling to a logical zero, pull-down circuit 204 enters in a high impedance state due to FET 305 being off. FET 303 of pull-up circuit 202 turns on, and after a short delay due to level shift circuit 208, FET 302 turns on. This rapidly charges internal signal 214 towards the voltage of memory cell supply 208. Inverter 308 then sets word line 108 at a logical zero.

In some embodiments, array 102 is partitioned into multiple banks of memory cells 104-105. In these embodiments, select signal 211 is a bank select signal for a particular bank of memory cells 104-105. In this case only one level shifter per bank of row drivers is used, with row drivers in the same bank utilizing the same level shifted signal. In this embodiment, select signal 212 may be a pre-decode signal that is generated based on an address for memory cells 104-105. Although only one select signal 212 is used as a pre-decode signal in this case, multiple pre-decode signals may be used by logically AND-ing the signals together in pull-down circuit 204 and logically OR-ing the signals together in pull-up circuit 203.

In other embodiments, array 102 is partitioned into one bank of memory cells 104-105. In these embodiments, select signal 211 is the most significant address bit for memory cells 104-105, and select signal 212 would be the least significant bit. In this case one level shifter is used for all of the row drivers. Although only one select signal 212 is used as the least significant bit in this case, multiple bits generated from the address information may be used by logically AND-ing the bit signals together in pull-down circuit 204 and logically OR-ing the signals together in pull-up circuit 203.

Utilizing decode-driver 116, word line 108 can be asserted quickly to the voltage of memory cell supply 208 to enable reading and writing to memory cells 104-105 of array 102. This occurs based on select signals 211-212, which transition between logic states at a different, lower, voltage of peripheral supply 209 without including level-shifters along the signaling path used to generate word line 108. By removing level-shifters from the access path for generating word line 108, signaling delays are reduced, which improves the performance of architecture 100.

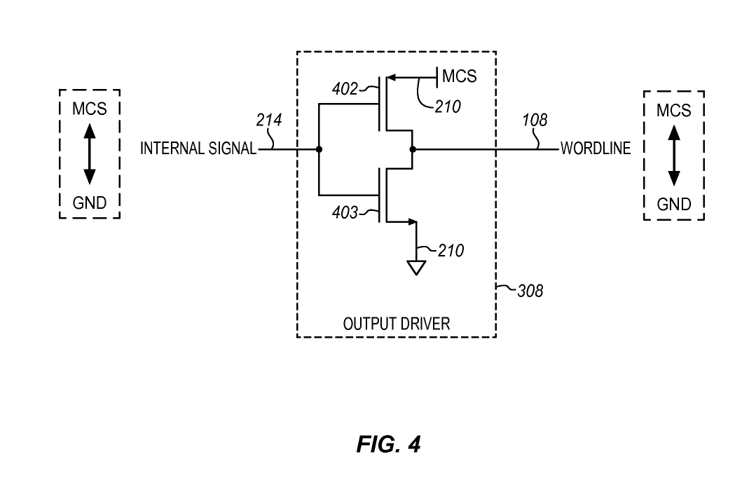

FIG. 4 is a schematic diagram illustrating additional details for decode-driver 116 of FIG. 3 in an exemplary embodiment. In this embodiment, a number of FETs 402-403 are illustrated in a particular configuration for implementing the functionality previously described for inverter 308 of FIG. 3. FETs 402-403 may include any type of field-effect transistor as a matter of design choice (e.g., MOSFETS). Although FIG. 4 illustrates one configuration of a number of FETs, one skilled in the art will understand other configurations may be implemented as a matter of design choice. Thus, it is not intended that inverter 308 be limited to only the configuration and types of components illustrated in FIG. 4.

In this embodiment, inverter 308 is implemented utilizing a push-pull configuration of FETs 402-403. FET 402 is a P-channel device with a source coupled to memory cell supply 208, a gate coupled to internal signal 214, and a drain coupled to word line 108. FET 403 is an N-channel device with a drain coupled to word line 108, a gate coupled to internal signal 214, and a source coupled to ground 210. With internal signal 214 at a logical zero voltage of approximately ground 210, FET 402 is on and FET 403 is off, which charges word line 108 to a logical one voltage at approximately memory cell supply 208. With internal signal 214 at a logical one voltage of approximately memory cell supply 208, FET 402 is off and FET 403 is on, which discharges word line 108 to a logical zero voltage at approximately ground 210. This inverts internal signal 214 and provides source/sink current to charge/discharge word line 108 rapidly based on internal signal 214.

What is claimed is:

1. A Static Random Access Memory (SRAM) device, comprising:
a memory cell array;
a word line traversing the memory cell array for selecting memory cells of the memory cell array;
a level shift circuit configured receive a first select signal that toggles between logic levels defined by a peripheral supply, and to translate the first select signal to logic levels defined by a memory cell supply to generate a level-shifted select signal; and
a row decode-driver configured to toggle the word line, the row decode-driver comprising:
an inverting driver coupled to the word line and configured to toggle the word line between the logic levels defined by the memory cell supply based on an internal signal;
a first pull-up circuit configured to couple the internal signal to the memory cell supply based on the level-shifted select signal and the first select signal;
a second pull-up circuit configured to couple the internal signal to the memory cell supply based on a logic level of the word line and a second select signal, wherein the second select signal toggles between the logic levels defined by the peripheral supply; and
a pull-down circuit configured to couple the internal signal to ground based on the first select signal and the second select signal.

2. The SRAM device of claim 1 wherein the first pull-up circuit comprises:
a first P-channel Field Effect Transistor (FET) having a source terminal coupled to the memory cell supply, a gate terminal coupled to the level-shifted select signal, and a drain terminal; and
a second P-channel FET having a source terminal coupled to the drain terminal of the first FET, a gate terminal coupled to the first select signal, and a drain terminal coupled to the internal signal.

3. The SRAM device of claim 1 wherein the second pull-up circuit comprises:
a first P-channel Field Effect Transistor (FET) having a source terminal coupled to the memory cell supply, a gate terminal coupled to the word line, and a drain terminal; and
a second P-channel FET having a source terminal coupled to the drain terminal of the first FET, a gate terminal coupled to the second select signal, and a drain terminal coupled to the internal signal.

4. The SRAM device of claim 1 wherein the pull-down circuit comprises:
a first N-channel Field Effect Transistor (FET) having a drain terminal coupled to the internal signal, a gate terminal coupled to the second select signal, and a source terminal; and
a second N-channel FET having a drain terminal coupled to the source terminal of the first FET, a gate terminal coupled to the first select signal, and a drain terminal coupled to ground.

5. The SRAM device of claim 1 wherein the inverting driver comprises:
a first P-channel Field Effect Transistor (FET) having a source terminal coupled to the memory cell supply, a gate terminal coupled to the internal signal, and a drain terminal coupled to the word line; and
a second N-channel FET having a drain terminal coupled to the word line, a gate terminal coupled to the internal signal, and a source terminal coupled to the ground.

6. The SRAM device of claim 1 wherein the ground is a common ground for the peripheral supply and the memory cell supply.

7. The SRAM device of claim 1 wherein the first select signal and the second select signal toggle to a logical one to set the word line to a logical one.

8. The SRAM device of claim 1 wherein the first select signal toggles to a logical zero to set the word line to a logical zero.

9. A Static Random Access Memory (SRAM) device, comprising:
a memory cell array;
a word line traversing the memory cell array for selecting memory cells of the memory cell array; and
a row decode-driver configured to toggle the word line, the row decode-driver comprising:
an inverting driver coupled to the word line and configured to toggle the word line between logic levels defined by a memory cell supply based on an internal signal;
a first P-channel Field Effect Transistor (FET) having a source terminal, a gate terminal coupled to a first select signal, and a drain terminal coupled to the internal signal, wherein the first select signal toggles between logic levels defined by a peripheral supply;
a second P-channel FET having a source terminal coupled to the memory cell supply, a drain terminal coupled to the source terminal of the first FET, and a gate terminal coupled to a level-shifted signal generated by translating the first select signal to the logic levels defined by the memory cell supply;
a third P-channel FET having a source terminal coupled to the memory cell supply, a gate terminal coupled to the word line, and a drain terminal;
a fourth P-channel FET having a source terminal coupled to the drain terminal of the third FET, a drain terminal coupled to the internal signal, and a gate terminal coupled to a second select signal, wherein the second select signal toggles between the logic levels defined by the peripheral supply;
a fifth N-channel FET having a drain terminal coupled to the internal signal, a gate terminal coupled to the second select signal, and a source terminal; and
a sixth N-channel FET having a drain terminal coupled to the source terminal of the fifth FET, a gate terminal coupled to the first select signal, and a drain terminal coupled to ground.

10. The SRAM device of claim 9 wherein the ground is a common ground for the peripheral supply and the memory cell supply.

11. The SRAM device of claim 9 wherein the first select signal and the second select signal toggle to a logical one to set the word line to a logical one.

12. The SRAM device of claim 9 wherein the first select signal toggles to a logical zero to set the word line to a logical zero.

13. The SRAM device of claim 9 wherein the inverting driver comprises:
a seventh P-channel FET having a source terminal coupled to the memory cell supply, a gate terminal coupled to the internal signal, and a drain terminal coupled to the word line; and
an eighth N-channel FET having a drain terminal coupled to the word line, a gate terminal coupled to the internal signal, and a source terminal coupled to the ground.

14. The SRAM device of claim 9 further comprising:
a level shift circuit configured to translate the first select signal from the logic levels of the peripheral supply to the logic levels of the memory cell supply.

15. A Static Random Access Memory (SRAM) device, comprising:
a memory cell array;
a word line traversing the memory cell array for selecting memory cells of the memory cell array, wherein the word line toggles between logic levels defined by a memory cell supply for the memory cells;
a plurality of decode lines for selecting the word line, wherein the plurality of decode lines toggle between logic levels defined by a peripheral supply;
a level shift circuit configured to receive a first decode signal received from one of the plurality of decode lines, and to translate the first decode signal to logic levels defined by the memory cell supply to generate a level-shifted decode signal; and
a row decode-driver configured to toggle the word line, the row decode-driver comprising:
an inverting driver having an output coupled to the word line and an input; and
a decode circuit coupled to the input of the inverting driver and configured to couple the input of the inverting driver to the memory cell supply based on the level-shifted decode signal, the first decode signal, a logic level of the word line, and a second decode signal;
the decode circuit further configured to couple the input of the inverting driver to ground based on the first decode signal and the second decode signal.

16. The SRAM device of claim 15 wherein a voltage of the peripheral supply is less than a voltage of the memory cell supply.

17. The SRAM device of claim 15 wherein the ground is a common ground for the peripheral supply and the memory cell supply.

18. The SRAM device of claim 15 wherein the first decode signal and the second decode signal toggle to a logical one to set the word line to a logical one.

19. The SRAM device of claim 15 wherein the first decode signal toggles to a logical zero to set the word line to a logical zero.

20. The SRAM device of claim 15 wherein the decoder comprises:
a first P-channel Field Effect Transistor (FET) having a source terminal coupled to the memory cell supply, a gate terminal coupled to the level-shifted decode signal, and a drain terminal;
a second P-channel FET having a source terminal coupled to the drain terminal of the first FET, a gate terminal coupled to the first decode signal, and a drain terminal coupled to the input of the inverting driver;
a third P-channel FET having a source terminal coupled to the memory cell supply, a gate terminal coupled to the word line, and a drain terminal;
a fourth P-channel FET having a source terminal coupled to the drain terminal of the third FET, a gate terminal coupled to the second decode signal, and a drain terminal coupled to the input of the inverting driver;
a fifth N-channel FET having a drain terminal coupled to the input of the inverting driver, a gate terminal coupled to the second decode signal, and a source terminal; and
a sixth N-channel FET having a drain terminal coupled to the source terminal of the fifth FET, a gate terminal coupled to the first decode signal, and a drain terminal coupled to the ground.
